(19) United States
(12) Patent Application Publication
(10) Pub. No.: US 2016/0276566 A1
(43) Pub. Date: Sep. 22, 2016

(54) Electrical Circuit and Method for Producing an Electrical Circuit

(71) Applicant: ROBERT BOSCH GMBH, Stuttgart (DE)

(72) Inventors: Tjalf Pirk, Stuttgart (DE); Ricardo Ehrenpfordt, Korntal-Muenchingen (DE); Frederik Ante, Stuttgart (DE); Johannes Kenntner, Magstadt (DE)

(21) Appl. No.: 15/032,841

(22) PCT Filed: Oct. 6, 2014
(86) PCT No.: PCT/EP2014/071347

§ 371 Date: Apr. 28, 2016

(30) Foreign Application Priority Data
Oct. 31, 2013 (DE) 10 2013 222 163.0

(51) Int. Cl. H01L 35/32; H01L 35/30; H01L 23/31

(52) U.S. Cl. CPC H01L 35/32; H01L 23/3121; H01L 35/30

(57) ABSTRACT

An electrical circuit includes a component, a thermoelectric generator, and a housing. The component is a sensor element configured to sense a quantity to be measured. The component is mechanically connected to an element side of a carrier element of the circuit. The thermoelectric generator is electrically connected to the component and mechanically connected to the carrier element. The thermoelectric generator is configured to supply the component with electrical energy by using a heat flow flowing through the thermoelectric generator. The housing is arranged on the element side of the carrier element and at least partially covers the component and the thermoelectric generator. The housing is configured to conduct the heat flow to the thermoelectric generator.

### PRIOR ART

The present invention relates to an electrical circuit and to a method for producing an electrical circuit.

In order to obtain electrical energy from a heat flow, a feed and a discharge of the heat flow to/from a thermoelectric generator are required.

DE 101 25058 A1 describes a thermally feedable transmitter and a sensor system.

### DISCLOSURE OF THE INVENTION

In light of the above, an electrical circuit and a method for producing an electrical circuit according to the main claim are presented with the approach presented here. Advantageous embodiments will emerge from the respective dependent claims and the following description.

An electrical circuit requires a housing for protection against ambient influences. A capability for guiding a heat flow to or from a thermoelectric generator of the circuit can be integrated in the housing. It is thus possible to dispense with an additional heat exchanger for the thermoelectric generator.

A self-sufficient electrical circuit can be provided economically and with small dimensions by the approach presented here.

An electrical circuit is presented, having the following features:

a component, in particular a sensor element for sensing a quantity to be measured, wherein the component is mechanically connected to an element side of a carrier element of the circuit;
a thermoelectric generator, which is electrically connected to the component and is also mechanically connected to the carrier element, wherein the thermoelectric generator is designed to supply the component with electrical energy with use of a heat flow flowing through the thermoelectric generator (and the carrier element); and
a housing, which is arranged on the element side of the carrier element and at least partially covers the component and the thermoelectric generator, wherein the housing is designed to conduct the heat flow to the thermoelectric generator.

An electrical circuit can be understood in particular to mean a self-sufficient sensor system. The electrical circuit can also be understood to be an electronic circuit. A component can be a microelectrical component, in particular a microelectromechanical component. A sensor element can be a microelectromechanical element. A carrier element can be a carrier substrate. By way of example, the carrier element can be a printed circuit board. An element side can be an upper side of the carrier element. The component can be glued or soldered onto the carrier element. A thermoelectric generator can have two different materials, between which two different electrical potentials are produced by a temperature difference. When the materials are interconnected on one side, an electrical voltage can be tapped between the other sides. When an electrical current is tapped, the temperature difference is reduced, thus resulting in a heat flow. Here, the heat flow flows from a higher temperature to the lower temperature.

The housing can be designed to conduct a fluid flow of a fluid to the thermoelectric generator, wherein the fluid is used as carrier medium for the heat flow. A fluid flow can be an airflow, for example. The housing can have conducting devices for the fluid flow, such as at least one duct. The housing can have openings for the fluid flow. The fluid flow can be transferred by convection.

The housing can have a first layer arranged directly on the carrier element and at least one second layer arranged on the first layer. The first layer can have a duct for conducting the fluid flow. The fluid flow can be purposefully conducted to the thermoelectric generator by a duct.

The housing can have a heat-conducting material and can be designed to conduct the heat flow to the thermoelectric generator via heat conduction. A heat-conducting material can be a metal. The housing can provide a considerably increased heat-transfer surface for the heat flow by means of the heat-conducting material.

The thermoelectric generator can be recessed at least partially in the carrier element. An overall height of the circuit can thus be reduced.

The housing can have direct, heat-conducting contact with the thermoelectric generator. A large heat flow density can be transferred and/or conducted via direct contact.

A heat-conducting heat-transfer element can be arranged between the housing and the thermoelectric generator, which element is thermally coupled to the housing and the thermoelectric generator. A heat-transfer element can bridge a distance between the housing and the thermoelectric generator.

The component can be a mass flow sensor. A mass flow sensor can quantify the fluid flow.

An intermediate layer can be arranged between the component and the carrier element. The intermediate layer can distance the component from the carrier element.

The carrier element can have at least one heat-conducting feedthrough for conducting the heat flow through the carrier element. The feedthrough can be thermally coupled to the thermoelectric generator. By means of the feedthrough, the carrier element can serve as a separation between a high temperature and a low temperature at the thermoelectric generator. The feedthrough can transport the heat flow particularly well.

The carrier element can have at least one aperture for conducting the heat flow through the carrier element. The aperture can be arranged in the region of a contact surface between the thermoelectric generator and the carrier element. A further fluid flow can transport the heat flow in the aperture.

The electrical circuit can have at least one further component, which is electrically connected to the thermoelectric generator, wherein the further component is designed to be supplied with electrical energy by the thermoelectric generator. The further component can be a further sensor element. The further component can be an integrated circuit. The circuit can perform further tasks as a result of the further component.

The Internet of Things (IoT) is referred to as one of the most important future developments in information technology. IoT is understood to mean that not only humans have access to the Internet and are networked thereby, but that devices are also networked with one another via the Internet. One area of the Internet of Things targets building and home automation, for example for temperature measurement. With sensors for smartphones (gyroscopes, acceleration sensors, pressure sensors, microphones), sensors which at the same time recover the required electrical energy from the environment using what are known as “energy harvesters” can be economically produced. By way of example, energy can be recovered from a temperature difference, for example at a heating system, using a thermoelectric generator (TEG).

The efficiency of a TEG is all the higher, the greater the temperature difference between the two active layers of the TEG, whereby the Seebeck effect is effective. Since the thermal conductivity of the TEG has a finite value, the temperature would come to be the same between the two active layers after a certain period of time without external heat flow. In this case it would no longer be possible to recover energy from the TEG. The cooler side of the TEG can therefore be thermally connected to a heat sink, typically made of metal. The heat from the heat flow can thus be delivered directly to the surroundings by the active layer, such that a sufficiently large temperature difference is maintained in the TEG itself.

With the approach presented here, the heat sink is integrated into the housing. A compact integration into the sensor system and reduced costs resulting from the omission of additional outlay for the manufacture and installation of the heat sink are thus possible.

By way of example, air can flow through the sensor element in order to release again the absorbed heat.

The approach presented here will be explained in greater detail hereinafter on the basis of the accompanying drawings, in which:

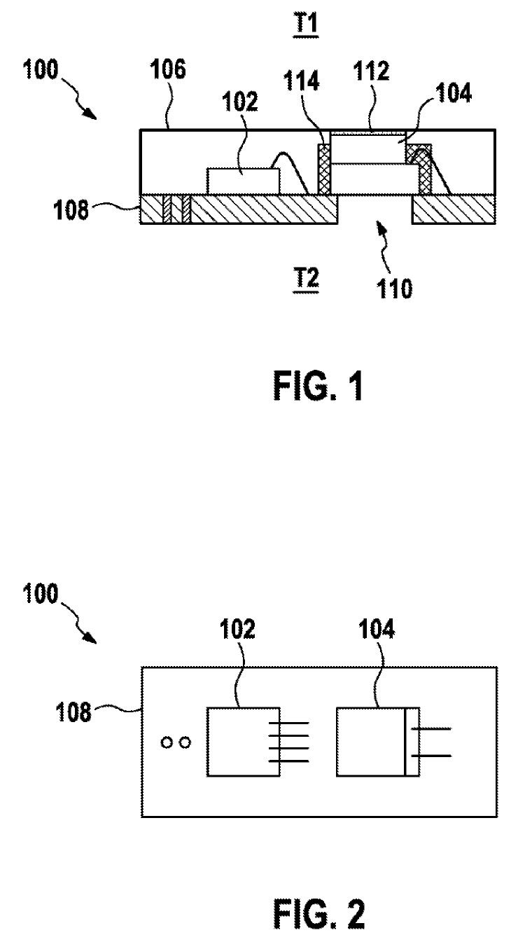

FIG. 1 shows a sectional illustration of an electrical circuit according to an exemplary embodiment of the present invention;

FIG. 2 shows a plan view of an electrical circuit according to an exemplary embodiment of the present invention;

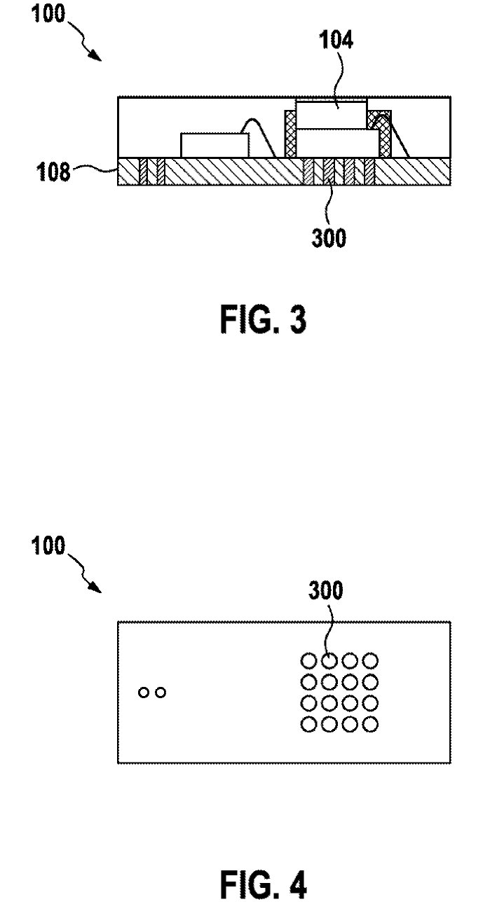

FIG. 3 shows a sectional illustration of an electrical circuit having thermal feedthroughs according to an exemplary embodiment of the present invention;

FIG. 4 shows a plan view of an electrical circuit having thermal feedthroughs according to an exemplary embodiment of the present invention;

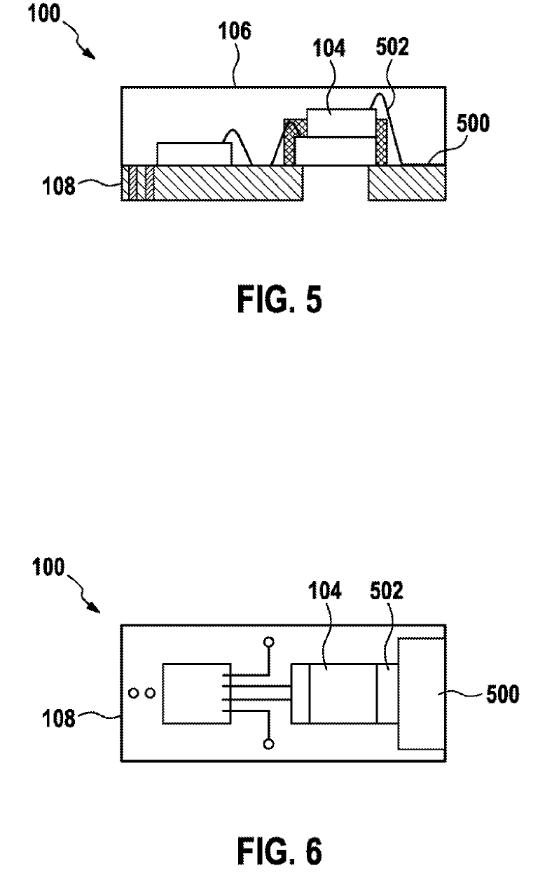

FIG. 5 shows a sectional illustration of an electrical circuit having a heat-transfer element according to an exemplary embodiment of the present invention;

FIG. 6 shows a plan view of an electrical circuit having a heat-transfer element according to an exemplary embodiment of the present invention;

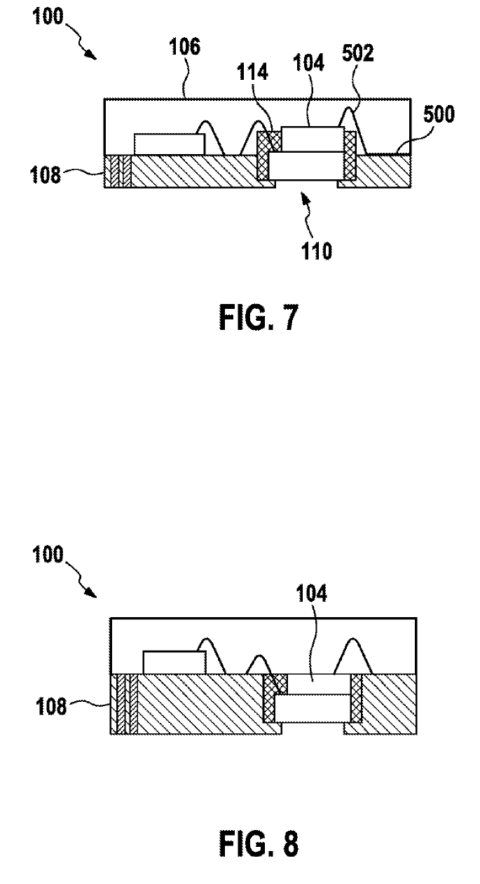

FIG. 7 shows a sectional illustration of an electrical circuit having a partially recessed thermoelectric generator according to an exemplary embodiment of the present invention;

FIG. 8 shows a sectional illustration of an electrical circuit having a recessed thermoelectric generator according to an exemplary embodiment of the present invention;

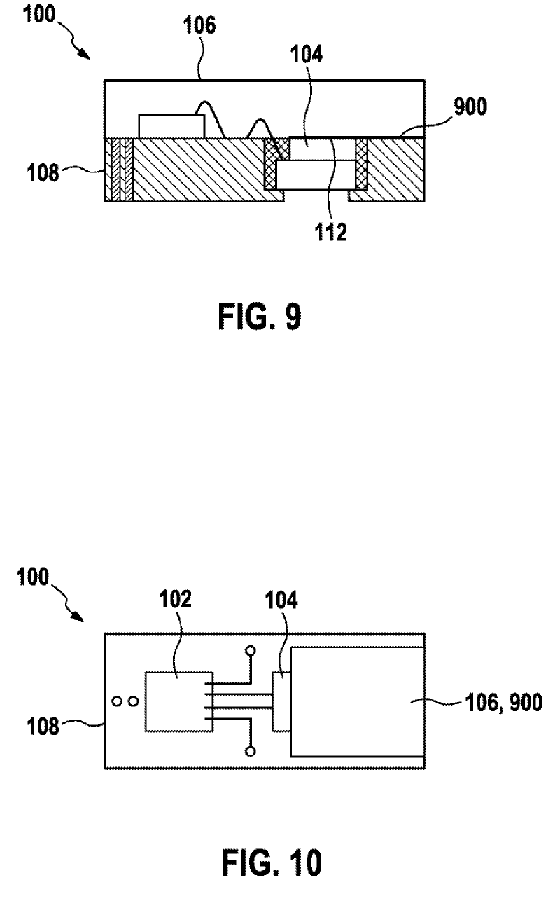

FIG. 9 shows a sectional illustration of an electrical circuit having an extended cover according to an exemplary embodiment of the present invention;

FIG. 10 shows a plan view of an electrical circuit having extended cover according to an exemplary embodiment of the present invention;

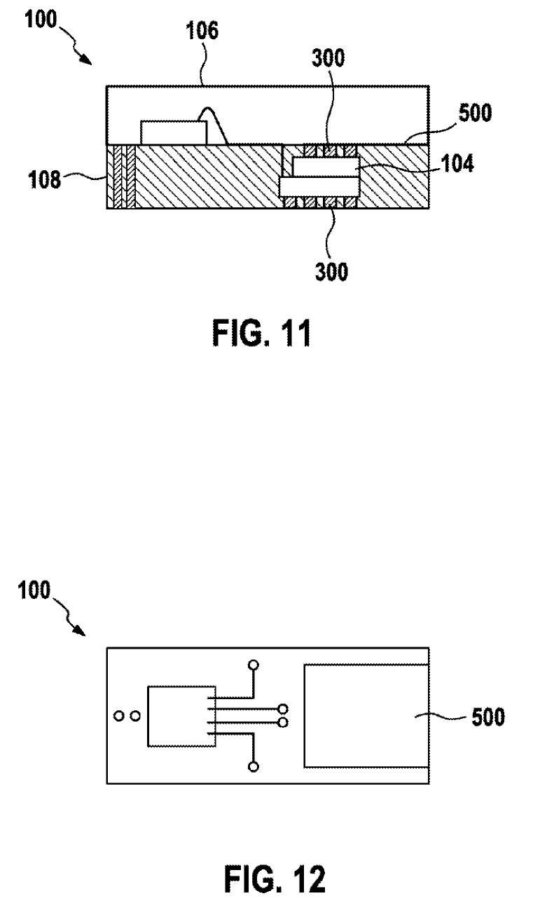

FIG. 11 shows a sectional illustration of an electrical circuit having an embedded thermoelectric generator according to an exemplary embodiment of the present invention;

FIG. 12 shows a plan view of an electrical circuit having a heat-transfer element according to an exemplary embodiment of the present invention;

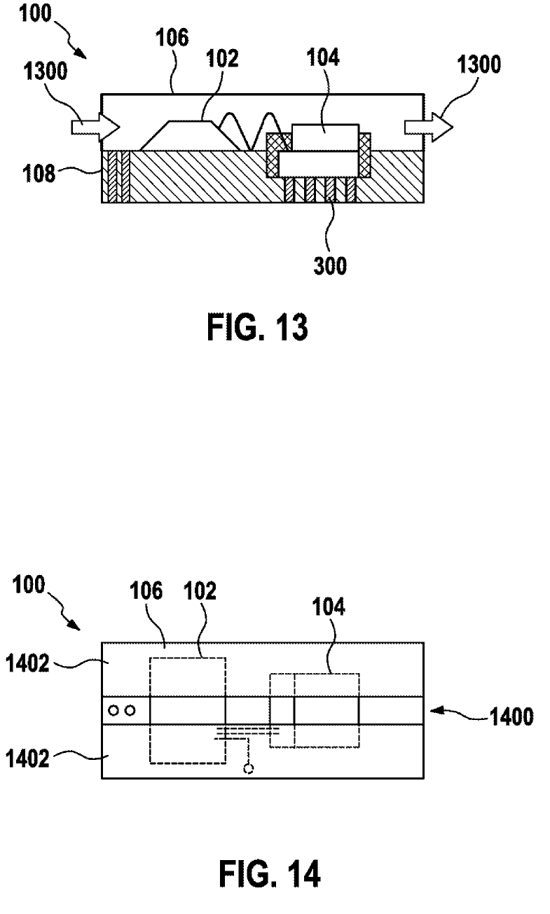

FIG. 13 shows a sectional illustration of an electrical circuit having a mass flow sensor according to an exemplary embodiment of the present invention;

FIG. 14 shows a plan view of an electrical circuit having a mass flow sensor according to an exemplary embodiment of the present invention;

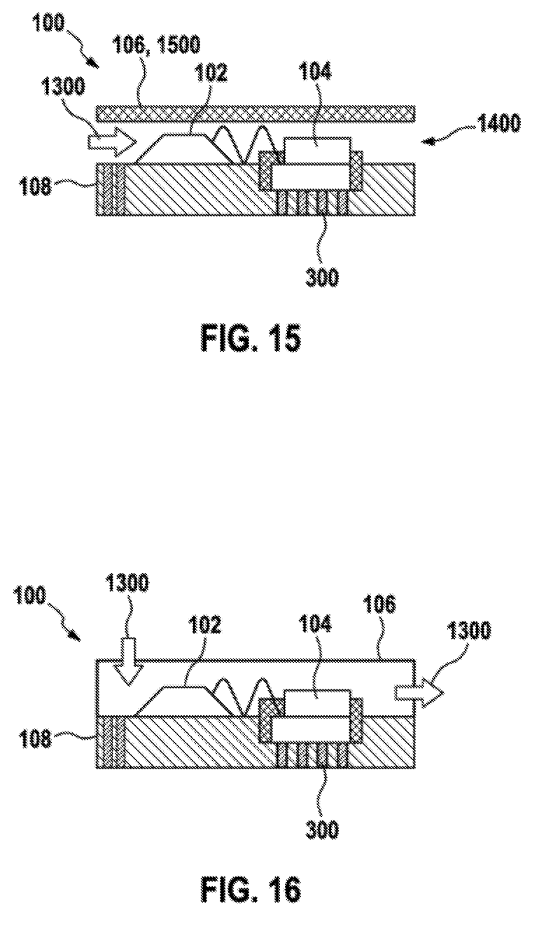

FIG. 15 shows a sectional illustration of an electrical circuit having a housing with a duct according to an exemplary embodiment of the present invention;

FIG. 16 shows a sectional illustration of an electrical circuit having an angled mass flow according to an exemplary embodiment of the present invention;

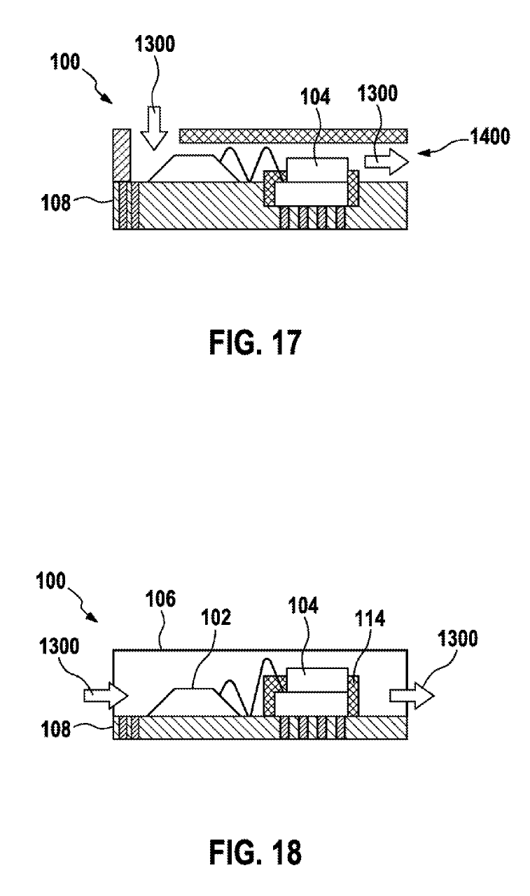

FIG. 17 shows a sectional illustration of an electrical circuit having a housing with a duct and angled mass flow according to an exemplary embodiment of the present invention;

FIG. 18 shows a sectional illustration of an electrical circuit having a fitted thermoelectric generator according to an exemplary embodiment of the present invention;

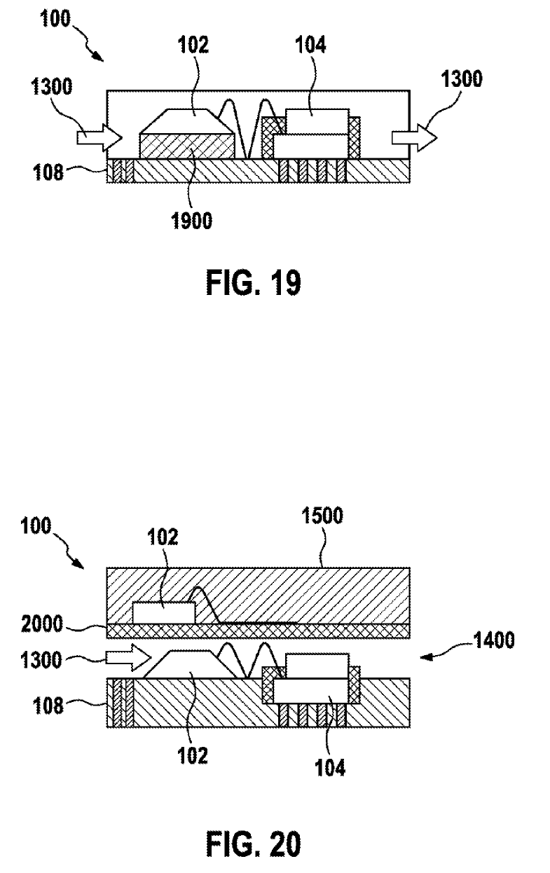

FIG. 19 shows a sectional illustration of an electrical circuit having a raised mass flow sensor in accordance with an exemplary embodiment of the present invention;

FIG. 20 shows a sectional illustration of an electrical circuit having a plurality of components according to an exemplary embodiment of the present invention;

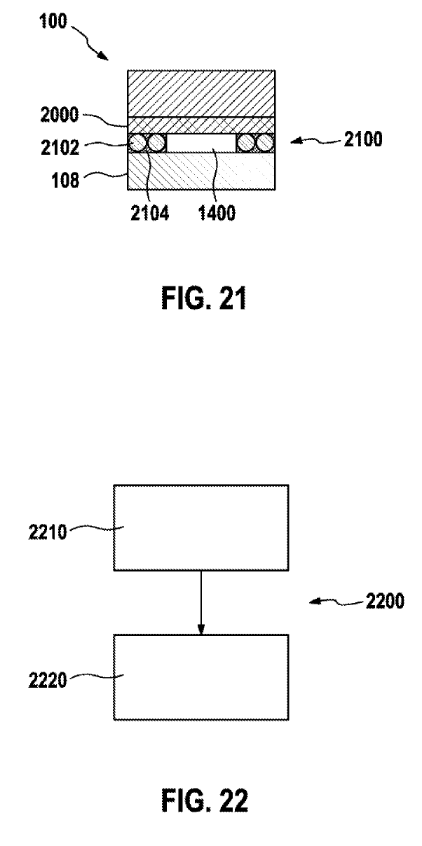

FIG. 21 shows a sectional illustration of an electrical circuit having a duct between stacked printed circuit boards according to an exemplary embodiment of the present invention; and

FIG. 22 shows a flow diagram of a method for producing an electrical circuit according to an exemplary embodiment of the present invention.

In the following description of favorable exemplary embodiments of the present invention, like or similar reference signs will be used for the similarly acting elements illustrated in the various figures, wherein a repeated description of these elements will not be provided.

FIG. 1 shows a sectional illustration of a side view of an electrical circuit 100 according to an exemplary embodiment of the present invention. The electrical circuit has a component 102, a thermoelectric generator 104 and a housing 106. The component 102 is mechanically connected to a first side of a carrier element 108 of the circuit 100. The first side can be referred to as the element side. The thermoelectric generator 104 is electrically connected to the component 102. The thermoelectric generator 104 is also mechanically connected to the carrier element 108. The thermoelectric generator 104 is designed to supply the component 102 with electrical energy with use of a heat flow flowing through the thermoelectric generator 104. The housing is arranged on the element side of the carrier element 108 and covers the component 102 and the thermoelectric generator 104. The housing 106 is designed to conduct the heat flow to the thermoelectric generator 104. The heat flow flows through the thermoelectric generator 104 when a first temperature T1 is applied to a first contact surface of the thermoelectric generator 104 and at the same time a second temperature T2 is applied to an opposite second contact surface of the thermoelectric generator 104 and there is a temperature difference ΔT between the first temperature T1 and the second temperature T2. The heat flow then flows from the higher temperature to the lower temperature.

In an exemplary embodiment the carrier element 108 has conductive tracks for conducting electrical current. The carrier element 108 may then be referred to as a printed circuit board 108. The component 102 and/or the thermoelectric generator 104 are connected to the conductive tracks of the printed circuit board 108 via wire bonds. Both the component 102 and the thermoelectric generator 104 can be soldered directly onto the printed circuit board 108.

In an exemplary embodiment the carrier element 108 has electrical feedthroughs or electrical vias from the element side to an opposed rear side.

In an exemplary embodiment the component 102 is a sensor element 102 for sensing a quantity to be measured. By way of example, the component 102 is a MEMS sensor 102 having wire bonds (microelectromechanical sensor).

In an exemplary embodiment the thermoelectric generator 104 is designed to supply the component 102 with electrical energy with use of a heat flow flowing through the thermoelectric generator 104 and the carrier element 108. The carrier element 108 is designed to locally thermally insulate the first temperature T1 from the second temperature T2 in order to conduct the heat flow through the thermoelectric generator 104.

In an exemplary embodiment the carrier element 108 has at least one aperture 110 for conducting the heat flow through the carrier element 108, wherein the aperture 110 is arranged in the region of a contact surface between the thermoelectric generator 104 and the carrier element 108. A fluid flow, such as an airflow, for transporting the heat flow can be led directly to the contact surface of the thermoelectric generator 104 through the aperture.

In an exemplary embodiment the housing 106 has a heat-conducting material 112 and is designed to conduct the heat flow to the thermoelectric generator 104 via heat conduction. By way of example, the housing 106 is made of metal or a metal cover and bears against the thermoelectric generator 104 in a heat-conducting manner. As a result of the heat-conducting material 112, the housing 106 has direct, heat-conducting contact with the thermoelectric generator 104.

In an exemplary embodiment a heat-conducting material 112 is arranged between the housing 106 and the thermoelectric generator 104. By way of example, the heat-conducting material 112 is a heat-conducting paste 112 or a gel as tolerance compensation. The heat-conducting material 112 is designed to compensate for a tolerance of the distance between the housing 106 and the thermoelectric generator 104. The heat-conducting material 112 forms a temperature bridge between the housing 106 and the thermoelectric generator 104.

In an exemplary embodiment the thermoelectric generator 104 rests on a surface of the carrier element 108. The thermoelectric generator 104 thus protrudes beyond the carrier element 108. In order to prevent a thermal short circuit between the first contact surface and the second contact surface, the thermoelectric generator 104 is insulated using a thermally insulating material 114. The thermally insulating material 114 surrounds the thermoelectric generator 104 on the side surfaces thereof and leaves the contact surfaces for the heat flow freely accessible.

In the exemplary embodiment described here the thermoelectric generator (TEG) 104 is in contact via the side T2 only with the ambient air. In the event that a heater for example is arranged on the side T2, a (thermally insulating) air space is thus formed between the heater and the surface T2 of the TEG 104. This cavity can be filled with heat-conducting paste for improved heat conductivity.

In an exemplary embodiment the aperture 110 through the carrier element 108 is filled with the heat-conducting material. As a result of the filling the heat flow can be transferred by direct heat conduction to a solid body in contact with the material.

In other words, FIG. 1 shows the thermal connection of a sensor cover 106 to a thermoelectric generator module 104.

The approach presented here describes a compact and economical thermoelectric generator (TEG) 104, which is integrated in an autonomous sensor system 100 having a base area of several cm². The TEG 104 here uses the metal cover 106 of the sensor system 100 as integrated heat sink.

By means of the approach presented here, there are no additional costs for a heat sink, since the metal cover 106 used as a heat sink is already provided for protection of the sensors 102. The thermal contacting of the cover 106 is provided here using technologies that are standard in printed circuit board engineering, such as copper tracks and/or thermal vias and/or using standard electronic packaging techniques, such as dispensing and/or screen printing. The use of a cover having a three-dimensional surface structure 106 may increase the cooling surface.

The exemplary embodiments shown here all have at least one thermoelectric generator (TEG) 104 having two temperature regions T1, T2, one or more different microelectromechanical (MEMS) sensors 102, a printed circuit board 108 and a metal cover 106. Here, only one sensor 102 in each case has been illustrated for simplification.

The TEG 104 requires a temperature difference between a first temperature T1 and a second temperature T2 in order to generate an electrical voltage. The hot and cold temperature side can be swapped here. In order to improve the efficacy of the TEG 104, the TEG 104 can be encased by a thermally insulating material 114, such that only the upper side and underside of the TEG 104 are exposed to the temperatures T1 and T2.

The TEG 104 and the one or more MEMS 102 are glued onto a printed circuit board 108 and are interconnected by means of wire bonds and a rewiring plane of the printed circuit board 108.

In an exemplary embodiment the printed circuit board 108 consists of FR4 material or of epoxy resin, which with heat conductivity of 0.3 W/mK is a thermal insulator compared with the metal cover 106. The metal cover 106 has a heat conductivity that is higher than the printed circuit board 108 by a number of magnitudes (more than 100 W/mK). This is advantageous since the printed circuit board 108 may thus constitute the boundary between the necessary temperatures T1 and T2. Furthermore, electrical vias may be located in the printed circuit board 108, which enable an electrical connection between the upper side and the underside of the printed circuit board 108.

The metal cover 106 is lastly placed on the printed circuit board 108 in order to protect the sensors 102 against ambient influences and damage, and additionally to perform the cooling function.

FIG. 2 shows a plan view of an electrical circuit 100 without cover according to an exemplary embodiment of the present invention. The circuit 100 corresponds substantially to the circuit in FIG. 1. The component 102 and the thermoelectric generator 104 are arranged in a central region of the carrier element 108.

In FIGS. 1 and 2 a side view and a view from above of a TEG 104 on a printed circuit board 108 having an opening or through-bore 110 are illustrated. In the simplest design of the approach presented here, the printed circuit board 108 has a bore 110. The MEMS 102 and TEG 104 are placed on the printed circuit board 108. The TEG 104 is surrounded by a thermally insulating material 114 for lateral insulation of the TEG 104. The opening 110 in the printed circuit board 108, via which opening for example air having the temperature T2 flows onto the TEG 104, is located directly below the TEG 104. The cover 106 is placed over the MEMS 102 and the TEG 102. In so doing, the cover 106 contacts the upper surface of the TEG 104 having the temperature T1. As tolerance compensation, a layer of heat-conducting paste 112 is introduced between the TEG 104 and the cover 106.

FIG. 3 shows a sectional illustration of an electrical circuit 100 having thermal feedthroughs 300 according to an exemplary embodiment of the present invention. The circuit 100 corresponds substantially to the circuit in FIG. 1. The carrier element 108 additionally has a plurality of heat-conducting feedthroughs 300 for conducting the heat flow through the carrier element 108, wherein the feedthroughs 300 are thermally coupled to the thermoelectric generator 104. The feedthroughs 300 are arranged on the carrier element 108 in the region of a contact surface of the thermoelectric generator 104. The feedthroughs 300 are formed as thermal vias 300. The feedthroughs 300 are formed as metal connections from the element side of the carrier element 108 to the rear side of the carrier element 108.

In an exemplary embodiment thermal vias 300, that is to say copper lines 300 between the upper side and underside of the printed circuit board 108, are integrated into the printed circuit board 108 locally below the position of the TEG 104. These thermal vias 300 are integrated already at the time of manufacture of the printed circuit board 108, with low additional costs. With regard to the other properties, this embodiment corresponds to the previously described possibilities.

FIG. 4 shows a plan view of an electrical circuit 100 having thermal feedthroughs 300 according to an exemplary embodiment of the present invention. The circuit 100 corresponds substantially to the circuit in FIG. 3. The feedthroughs 300 are arranged in the illustrated exemplary embodiment in a grid consisting of four columns and four rows of feedthroughs 300 distanced regularly from one another. The number and arrangement of the feedthroughs 300 is merely exemplary here and can be adapted to the contact surface of the thermoelectric generator.

Besides these three main variants of printed circuit board 108 with bore 110, bore 110 and heat-conducting paste, or thermal vias 300, further modifications are also possible. By way of example, only the embodiment “printed circuit board 108 with bore 110” will be discussed for all following exemplary embodiments. The other two variants can also be implemented in each case.

FIG. 5 shows a sectional illustration of an electrical circuit 100 having a heat-transfer element 500 according to an exemplary embodiment of the present invention. The circuit 100 corresponds substantially to the circuit in FIG. 1. In contrast thereto, the housing 106 is formed here at a distance from the thermoelectric generator 104. The heat-transfer element 500 is arranged between the housing 106 and the thermoelectric generator 104. The heat-transfer element 500 is heat-conductive. The heat-transfer element 500 is thermally coupled to the housing 106 and the thermoelectric generator 104. By means of the heat-transfer element 500, the housing 106 has direct, heat-conductive contact with the thermoelectric generator 104. The heat-transfer element 500 is arranged on the element side of the carrier element 108. The heat-transfer element 500 is formed as a metal layer 500 or metallization layers 500 on the printed circuit board 108, in particular as a copper layer 500 on the carrier element 108 between an edge of the carrier element 108 and the thermoelectric generator 104. The heat-transfer element 500 is connected via a copper strip 502 to the contact surface of the thermoelectric generator 104.

In an exemplary embodiment the TEG 104 is not coupled to the side T1 directly at the cover 106, which here is a metal cover, but via a copper strip 502 and/or copper layers 500 on the printed circuit board 108, such that the cover 106 is contacted at the lower edge so to speak. The copper strips 502 can be glued in this case. An advantage of this is that the tolerance compensation between the height of the cover and the upper side TEG 104 is eliminated.

FIG. 6 shows a plan view of an electrical circuit 100 having a heat-transfer element 500 according to an exemplary embodiment of the present invention. The circuit 100 corresponds substantially to the circuit in FIG. 5. The heat-transfer element 500 extends over approximately a width of the carrier element 108. The heat-transfer element 500 is wider than the thermoelectric generator 104. The copper strip 502 has the same width as the thermoelectric generator 104.

FIG. 7 shows a sectional illustration of an electrical circuit 100 having a partially recessed thermoelectric generator 104 according to an exemplary embodiment of the present invention. The circuit 100 corresponds substantially to the circuit in FIG. 5. In contrast thereto, the thermoelectric generator 104 is embedded in the carrier element 108, and the housing is similarly low, as in FIG. 1. In order to embed the thermoelectric generator 104, the carrier element 108 has a stepped bore, the smaller diameter of which represents the aperture 110, whereas the larger diameter serves as a receptacle for part of the thermoelectric generator 104. Here, the large diameter is larger than the thermoelectric generator 104. The thermoelectric generator 104 is integrally cast in the stepped bore with use of the thermally insulating material 114. As in FIG. 5, the housing 106 is thermally coupled via the heat-transfer element 500 and the copper strip 502 to the contact surface of the thermoelectric generator 104.

In an exemplary embodiment the TEG 104 is inserted or integrated in part into the printed circuit board 108. Here, the printed circuit board 108 has a blind bore (large diameter) followed by a through-bore 110 (small diameter). The TEG 104 rests on the resultant protrusion. The hole is filled with thermally insulating (filler) material 114. The TEG 104 side T1 is contacted as before via copper strips 502. The TEG 104 can also be contacted directly via the cover 106.

FIG. 8 shows a sectional illustration of an electrical circuit 100 having a recessed thermoelectric generator 104 according to an exemplary embodiment of the present invention. The circuit 100 corresponds substantially to the circuit in FIG. 7. In contrast thereto, the thermoelectric generator 104 is completely embedded in the carrier element 108. For this purpose, the carrier element 108 is thicker than the thermoelectric generator 104. A depth of the large diameter of the stepped bore is adapted to a height of the thermoelectric generator 104. The contact surface of the thermoelectric generator 104 terminates in a planar manner with the element side of the carrier element 108.

FIG. 9 shows a sectional illustration of an electrical circuit 100 having an extended cover 106 according to an exemplary embodiment of the present invention. The circuit 100 corresponds substantially to the circuit in FIG. 8. The housing 106 is referred to here as a cover 106. In contrast to FIG. 8, the contact surface of the thermoelectric generator 104 is coupled here to the cover 106 without the heat-transfer element. For this purpose, the cover 106 has a flange 900 resting on the carrier element 108.

In an exemplary embodiment, heat-conducting paste 112 is arranged between the contact surface and the flange in order to improve the transfer of heat from the cover 106 to the thermoelectric generator 104 and in order to compensate for any tolerances present.

The exemplary embodiment shown here, in particular, provides the possibility of being able to select an alternative cover form as extended cover concept. In FIG. 9 this exemplary embodiment is shown with a cover 106 that is folded inwardly in part. The contacting of the TEG 104 side T1 with copper bands is thus omitted, and the thermal contacting is ensured by the fitting of the cover 106. Heat-conducting paste may again serve as tolerance compensation. In other words, FIG. 9 shows a metal cover 106 folded-in at the bottom in order to enable thermal contacting of the TEG 104. Heat-conducting paste 112 can be used as thickness tolerance.

FIG. 10 shows a plan view of an electrical circuit 100 having an extended cover 106 according to an exemplary embodiment of the present invention. The circuit 100 corresponds substantially to the circuit in FIG. 9. The flange 900 of the housing 106 covers the thermoelectric generator 104 in order to enable the electrical connection of the thermoelectric generator 104 to the component 102.

FIG. 11 shows a sectional illustration of an electrical circuit 100 having an embedded thermoelectric generator 104 according to an exemplary embodiment of the present invention. The circuit 100 corresponds substantially to the circuit in FIG. 9. In contrast thereto, the thermoelectric generator 104 has been embedded here in the carrier element 108 already during the production of the carrier element 108. The thermoelectric generator 104 is thermally contacted via feedthroughs 300 to both contact surfaces. The heat flow is conducted to the thermoelectric generator 104, as in FIG. 5, via a copper layer 500 on the carrier element 108 as heat-transfer element 500. Since the feedthroughs 300 terminate flush on both sides of the carrier element 108, the heat-transfer element 500 is directly connected to the feedthroughs.

In an exemplary embodiment the TEG 104 is introduced completely into the printed circuit board 108 by means of embedding technology, i.e. during the production process of the printed circuit board 108. The thermal contacting of the TEG 104 is ensured by thermal vias 300. The electrical contracting is ensured by electrical vias. The heat flow from the TEG 104 side T2 is diverted toward the metal cover 106 using copper layers 500, for example.

FIG. 12 shows a plan view of an electrical circuit 100 having a heat-transfer element 500 according to an exemplary embodiment of the present invention. The circuit 100 corresponds substantially to the circuit in FIG. 10. The heat-transfer element 500 covers the feedthroughs completely.

FIG. 13 shows a sectional illustration of an electrical circuit 100 having a mass flow sensor 102 according to an exemplary embodiment of the present invention. The circuit 100 corresponds substantially to the circuit in FIG. 7. In contrast to FIG. 7, the component 102 here is a mass flow sensor 102. In addition, the housing 106 is designed to conduct a fluid flow 1300 of a fluid to the thermoelectric generator 104, wherein the fluid is used as carrier medium for the heat flow. Furthermore, the carrier element 108, instead of the aperture, has feedthroughs 300 for guiding the heat flow through the carrier element 108. In order to be permeable for the fluid flow 1300, the housing 106 has, at diametrically opposed ends, lateral openings for the fluid flow 1300. When the fluid flow 1300 flows through the housing 106, the heat load is transferred by convection between the contact surface of the thermoelectric generator 104 and the fluid flow 1300. The housing 106 is formed here as a thin-walled cover 106.

In other words, FIG. 1300 shows a compact fluidic energy harvester package 100.

In the exemplary embodiment shown here the mass flow 1300 having the temperature T1, which will be referred to hereinafter as the airflow 1300, is not only measured, but at the same time is used for heat exchange on the side T1 of the TEG 104. Here, it is the flow that is measured, and not the temperature. The other temperature side T2 of the TEG 104 is connected to the temperature reservoir T2 via the printed circuit board 108. The electrical energy produced here is used directly to operate the mass flow sensor 102 and further integrated components, for example a radio module, temperature sensor, etc.

With the approach presented here a TEG 104, a mass flow sensor 102, and possibly further sensors for temperature, radio modules, ASICs, are integrated into a housing 100 such that the mass flow 1300 or airflow 1300 is not only measured by the mass flow sensor 102, but at the same time is also used for heat exchange on one side of the TEG 104.

In an exemplary embodiment a TEG 104 and a mass flow sensor 102 are jointly integrated. By use of a TEG 104 for energy recovery, there is no need for a battery in the sensor element 100. There is no need for an additional heat sink for the TEG 104. This reduces the overall size considerably and additionally reduces the costs. The TEG 104 enables autonomous operation at locations which for example are unsuitable for vibration harvesters. The sensor system presented here can also be used without direct solar irradiation, which would be required for PV cells as energy harvesters. By way of example, operation at the transition of a ventilation shaft of an air-conditioning system to an office space is possible, such that the temperature difference between cooled supply air and the warmer room climate can be optimally utilized.

FIG. 14 shows a plan view of an electrical circuit 100 having a mass flow sensor 102 according to an exemplary embodiment of the present invention. The circuit 100 corresponds substantially to the circuit in FIG. 13. In addition, the housing 106 has a duct 1400 for conducting the fluid flow. The duct 1400 extends in a straight line from one end of the circuit 100 to the other end of the circuit 100. In particular, the duct 1400 extends from an opening in the housing 106 to the other opening in the housing 106. Outside the duct 1400, the parts of the circuit 100 are covered by a protective material 1402. Both an active structure of the mass flow sensor 102 and the contact surface of the thermoelectric generator 104 are exposed within the duct 1400.

In other words, the printed circuit board 108 is covered outside the duct 1400 by a material 1402 for protecting against corrosion and for providing a channeling.

In a simple exemplary embodiment the mass flow sensor 102 and the TEG 104 are mounted on a printed circuit board 108 using standard techniques and are housed with a cover 106 made of plastic and/or metal. The printed circuit board 108 may comprise a plurality of metallization planes. The uppermost metallization plane contains the rewiring of the sensors 102 and of the TEG 104 to one another. Further components, such as radio modules, temperature sensors, and ASICs are not shown for improved clarity, but can be located in this sensor element 100. The printed circuit board 108 may additionally comprise electrical vias between the individual metallization planes. Metal surfaces may also be located on the underside in order to electrically contact the sensor system 100 or in order to solder it directly onto a further printed circuit board.

The TEG 104 is mechanically and thermally connected via the side T2 to the printed circuit board 108. This can be realized for example by thermal vias.

In order to measure the mass flow 1300 and in order to enable a temperature exchange on the side T2 of the TEG 104, the cover 106 has lateral openings. Since the other electronic components 102 (sensors) and the electrical conductive tracks and bond wires can be exposed to the ambient conditions through these openings in the cover 106, a protective layer can be applied to the sensitive component parts and conductive tracks/wire bonds.

Due to the protective layer, corrosion can be prevented, for example. The reliability of the module 100 can thus be improved. The protective layer can be constructed for example by dispensing a suitable passivation polymer. In addition, this polymer can be used in order to channel the mass flow through the component 100.

FIG. 15 shows a sectional illustration of an electrical circuit 100 having a housing 106 with duct 1400 according to an exemplary embodiment of the present invention. The circuit 100 corresponds substantially to the circuit in FIG. 13. In contrast thereto, the housing 106 is formed solidly from a housing material 1500, with the exception of the duct 1400.

In an exemplary embodiment the duct 1400 for conducting the fluid flow 1300 has been produced with use of a removable material. Here, the removable material has been used as a placeholder for the duct 1400. When applying the housing material 1500, the housing material 1500 flows around the placeholder and is cured. The removable material is then removed in order to form the duct 1400 through the housing material 1500.

In an exemplary embodiment the duct 1400 for conducting the fluid flow 1300 has been produced with use of a prefabricated housing 106. For this purpose, the housing material 1500 has been poured into a mold, cured in the mold, and removed from the mold in the cured state. Here, the mold forms a negative impression of the housing 106 and of the duct 1400. The finished housing 106 has been fitted onto the carrier element 108 with the component 102 and the thermoelectric generator 104 with use of an adhesive layer.

As in FIG. 14, active surfaces of the component 102 and of the thermoelectric generator 104 are exposed within the duct 1400.

In an exemplary embodiment the structure, as shown in FIG. 13, is formed with ducts in a molding compound 1500 instead of by a cover. The molding compound 1500 is a thermoset and can be used in order to permanently protect sensors 102 against ambient influences. For this purpose, the entire system 100 is overmolded during the molding process, and all regions are permanently covered. With thermally decomposable polymers as sacrificial layer, a duct 1400 can be formed in the molding compound 1500. For this purpose, the region of the subsequent duct 1400 is covered or structured with the decomposable polymer prior to molding. The sensor system 100 is then overmolded with the thermoset 1500. If the system 100 is then heated to a certain temperature, the polymer decomposes without residue, and a duct 1400 is formed in the molding compound 1500.

FIG. 16 shows a sectional illustration of an electrical circuit 100 having an angled mass flow 1300 according to an exemplary embodiment of the present invention. The circuit 100 corresponds substantially to the circuit in FIG. 13. In contrast thereto, the opening in the housing 106 through which the fluid flow 1300 can flow in or out is arranged on the side of the housing 106 facing away from the carrier element 108. The fluid flow 1300 is thus deflected in the housing at right angles and flows in the housing 106 substantially along the carrier element 108 and therefore over the thermoelectric generator 104 and the mass flow sensor 102.

FIG. 17 shows a sectional illustration of an electrical circuit 100 having a housing 106 with duct 1400 and angled mass flow 1300 according to an exemplary embodiment of the present invention. The circuit 100 corresponds substantially to the circuit in FIG. 16. In contrast thereto, the housing 106 as in FIG. 15 is made of the housing material 1500 and comprises the duct 1400 with angled mass flow 1300, as in FIG. 16.

The airflow 1300 through the sensor element 100 can be oriented differently depending on requirements. By way of example, the cover 106 may have an opening on the upper side, and the ducts 1400 in the molding compound 1500 may also extend other than laterally. By way of example, the ducts 1400 can be oriented vertically, such that an opening on the upper side is possible.

In an exemplary embodiment, instead of molding and sacrificial layer, a plastics cover prefabricated by injection molding (pre-mold) is used in order to ensure the duct 1400 or the channeling in the molding compound 1500. Apart from an additionally required adhesive layer for gluing the premold cover, the design does not differ from the previously described exemplary embodiments.

FIG. 18 shows a sectional illustration of an electrical circuit having a fitted thermoelectric generator according to an exemplary embodiment of the present invention. The circuit 100 corresponds substantially to the circuit in FIG. 13. As in FIG. 13, the component 102 is formed as a mass flow sensor 102 and is designed to sense the mass flow 1300 through the housing 106. In contrast thereto, the thermoelectric generator 104 as in FIG. 3 is arranged resting on the carrier element 108. The thermoelectric generator 104 is insulated by the insulating material 114 in order to avoid a thermal short circuit.

In the previously presented exemplary embodiment the TEG 104 was recessed slightly in the printed circuit board 108, such that the airflow 1300 through the package 100 is not swirled at the protruding TEG 104.

In a further exemplary embodiment the TEG 104 is arranged on the printed circuit board 108. The swirling of the air does not significantly influence the operation of the sensor element 102. In this case the TEG 104 is thermally insulated at the side walls using an insulating material 114, since otherwise a thermal short circuit could be produced between the two temperature sides T1 and T2.

FIG. 19 shows a sectional illustration of an electrical circuit 100 having a raised mass flow sensor 102 according to an exemplary embodiment of the present invention. The circuit 100 corresponds substantially to the circuit in FIG. 18. In addition, an intermediate layer 1900 is arranged between the component 102 and the carrier element 108. The intermediate layer 1900 distances the component 102 from the carrier element 108, such that said component is arranged in a region of the fluid flow 1300 in which reduced interference of the flow by the thermoelectric generator 104 is anticipated. The mass flow sensor 102 can thus operate particularly well.

In an exemplary embodiment the height of the mass flow sensor 102 is adapted to the height of the TEG 104 using spacers 1900 made of plastic or metal in order to optimize the airflow through the sensor element 100. An adaptation of the relative height of the mass flow sensor 102 and of the TEG 104 to one another is thus achieved. The spacer 1900 can be formed for example as a plastics platelet or metal platelet.

FIG. 20 shows a sectional illustration of an electrical circuit 100 having a plurality of components 102 according to an exemplary embodiment of the present invention. The circuit 100 corresponds substantially to the circuit in FIG. 15. In contrast thereto, the duct 1400 is formed between the carrier element 108 and a further carrier element 2000. The carrier elements 108, 2000 are distanced from one another. The distance between the carrier elements 108, 2000 corresponds here to a height of the duct 1400. Outside the duct 1400, the carrier elements 108, 2000 are interconnected via spacers. The first component 102 is formed as a mass flow sensor 102 and is arranged within the channel 1400 for the fluid flow 1300. The at least one further component 102 is electrically connected to the thermoelectric generator 104. The further component 102 is designed to be supplied with electrical energy by the thermoelectric generator 104. The further component 102 is arranged on a side of the further carrier element 2000 opposite the duct 1400. Housing material 1500 is cast around the further component 102. The circuit 100 has conductive tracks for connecting the upper and lower module 102.

In an exemplary embodiment the further component 102 is a further sensor 102 for sensing a further quantity to be measured.

In an exemplary embodiment the further component 102 is an integrated circuit 102 for processing sensor signals of the first sensor 102.

In an exemplary embodiment the housing 106 has a first layer arranged directly on the carrier element 108 and at least one second layer arranged on the first layer. The first layer comprises the duct 1400 for conducting the fluid flow 1300.

In an exemplary embodiment the duct 1400 is formed by the stacking of a plurality of printed circuit boards 108, 2000. By way of example, a package-on-package (PoP) 100 is shown in FIG. 20. In the case of packaging by PoP, two or more packages are placed one above the other and are electrically and mechanically connected using solder balls. In this method it is very easily possible for example to omit some solder balls on opposite sides and to close the rest of the solder balls using an underfiller as seal material or using an additional sealing ring made of solder paste. In this way an air duct 1400 is produced between two packages 108, 2000. Critical structures on the printed circuit board 108 of the TEG 104 and/or of the mass flow sensor 102 may optionally be covered by a protective layer.

FIG. 21 shows a sectional illustration of an electrical circuit 100 having a duct 1400 between stacked printed circuit boards 108, 2000 according to an exemplary embodiment of the present invention. A detail of the circuit illustrated in FIG. 20 is illustrated. Here, the duct 1400 is shown along its longitudinal axis. The spacers 2100 have metal support elements 2102 and a filling compound 2104. The support elements 2102 define the distance between the printed circuit boards 108, 2000. The filling compound 2104 seals off gaps between the support elements 2102.

FIG. 22 shows a flow diagram of a method 2200 for producing an electrical circuit according to an exemplary embodiment of the present invention. The method 2200 comprises a step of providing 2210 a component, in particular a sensor element for sensing a quantity to be measured, a thermoelectric generator, which is electrically connected to the component and is also mechanically connected to the carrier element, wherein the thermoelectric generator is designed to supply the component with electrical energy with use of a heat flow flowing through the thermoelectric generator, and a housing, wherein the housing is designed to conduct the heat flow to the thermoelectric generator. The method 2200 also comprises a step 2220 of arranging the housing on the element side of the carrier element in such a way that it at least partially covers the component and the thermoelectric generator.

The exemplary embodiments described and shown in the figures have been selected merely by way of example. Different exemplary embodiments can be combined with one another fully or in respect of individual features. An exemplary embodiment can also be supplemented by features of a further exemplary embodiment.

Method steps according to the invention can also be repeated as well as performed in an order different from that described.

If an exemplary embodiment includes an “and/or” link between a first feature and a second feature, this is to be interpreted such that the exemplary embodiment according to one embodiment includes both the first feature and the second feature and according to a further embodiment includes either only the first feature or only the second feature.

1. An electrical circuit, comprising:
at least one component configured to sense a quantity to be measured, the component mechanically connected to an element side of a carrier element of the circuit;
a thermoelectric generator electrically connected to the component and mechanically connected to the carrier element, the thermoelectric generator configured to supply the component with electrical energy with use of a heat flow flowing through the thermoelectric generator; and
a housing arranged on the element side of the carrier element and at least partially covering the component and the thermoelectric generator, the housing configured to conduct the heat flow to the thermoelectric generator.

2. The electrical circuit as claimed in claim 1, wherein the housing is further configured to conduct a fluid flow of a fluid to the thermoelectric generator, the fluid configured to be used as carrier medium for the heat flow.

3. The electrical circuit as claimed in claim 2, wherein the housing has a first layer arranged directly on the carrier element and at least one second layer arranged on the first layer, the first layer having a duct configured to conduct the fluid flow.

4. The electrical circuit as claimed in claim 1, wherein the component is a mass flow sensor.

5. The electrical circuit as claimed in claim 1, wherein the housing comprises a heat-conducting material and is thermally coupled to the thermoelectric generator.

6. The electrical circuit as claimed in claim 1, wherein a heat-conducting heat-transfer element is arranged between the housing and the thermoelectric generator, the heat-conducting heat-transfer element thermally coupled to the housing and the thermoelectric generator.

7. The electrical circuit as claimed in claim 1, wherein the thermoelectric generator is at least partially recessed in the carrier element.

8. The electrical circuit as claimed in claim 1, wherein an intermediate layer is arranged between the component and the carrier element.

9. The electrical circuit as claimed in claim 1, wherein the carrier element has at least one heat-conducting feedthrough configured to conduct the heat flow through the carrier element, the at least one heat-conducting feedthrough thermally coupled to the thermoelectric generator.

10. The electrical circuit as claimed in claim 1, wherein the carrier element has at least one aperture configured to conduct the heat flow through the carrier element, the aperture arranged in the region of a contact surface between the thermoelectric generator and the carrier element.

11. The electrical circuit as claimed in claim 1, further comprising at least one further component that is electrically connected to the thermoelectric generator, the further component configured to be supplied with electrical energy by the thermoelectric generator.

12. A method for producing an electrical circuit, comprising:
mechanically connecting at least one component to an element side of a carrier element of the circuit, the component configured to sense a quantity to be measured;
electrically connecting a thermoelectric generator to the component and mechanically connecting the thermoelectric generator to the carrier element, the thermoelectric generator configured to supply the component with electrical energy with use of a heat flow flowing through the thermoelectric generator; and
arranging a housing on the element side of the carrier element in such a way that the housing at least partially covers the component and the thermoelectric generator, the housing configured to conduct heat flow to the thermoelectric generator.

13. The electrical circuit as claimed in claim 1, wherein the at least one component is configured as a sensor element.

14. The method as claimed in claim 12, wherein the at least one component is configured as a sensor element.
